(19) United States
(12) Patent Application Publication
(10) Pub. No.: US 2021/0366940 A1
(43) Pub. Date: Nov. 25, 2021

(54) MANUFACTURING METHOD OF ARRAY SUBSTRATE, ARRAY SUBSTRATE, DISPLAY PANEL AND DISPLAY DEVICE

(71) Applicants: Beijing BOE Display Technology Co., Ltd., Beijing (CN); BOE Technology Group Co., Ltd., Beijing (CN)

(72) Inventors: Fangbin Fu, Beijing (CN); Huibin Guo, Beijing (CN); Jinchao Bai, Beijing (CN); Shoukun Wang, Beijing (CN); Hao Han, Beijing (CN); Yihe Jia, Beijing (CN); Yongzhi Song, Beijing (CN)

(21) Appl. No.: 16/471,619

(22) PCT Filed: Nov. 7, 2018
(86) PCT No.: PCT/CN2018/114396

§ 371 Date: Jun. 20, 2019

(30) Foreign Application Priority Data
Mar. 23, 2018 (CN) 201810247365.2

(51) Int. Cl. H01L 27/12

(52) U.S. Cl. CPC H01L 27/1222; H01L 27/1288; H01L 27/127

(57) ABSTRACT

The present disclosure discloses a manufacturing method of an array substrate, an array substrate, a display panel and a display device. The manufacturing method includes: forming a metal layer on a base substrate; forming a protective layer on the side, away from the base substrate, of the metal layer, wherein the protective layer is configured to protect the metal layer; forming photoresist on the side, away from the base substrate, of the protective layer; and processing the base substrate, on which the metal layer, the protective layer and the photoresist are formed, by means of a photoetching process to obtain a metal pattern.

### CROSS-REFERENCE TO RELATED APPLICATION

This application is a 371 of PCT Patent Application Serial No. PCT/CN2018/114396, filed on Nov. 7, 2018, which claims priority to Chinese Patent Application No. 201810247365.2, filed on Mar. 23, 2018 and entitled “Array substrate and manufacturing method thereof, display panel and display device”, the entire contents of which are incorporated herein by reference.

### TECHNICAL FIELD

The present disclosure relates to a manufacturing method of an array substrate, an array substrate, a display panel and a display device.

### BACKGROUND

In a display panel, an array substrate generally include gate line, data lines and a plurality of thin film transistors in an array. Each TFT is connected to a gate line and a data line. Each TFT includes a gate pattern, an active layer pattern and a source/drain pattern. The gate line, the data line, the gate pattern and the source/drain pattern are generally metal patterns.

Generally, the metal pattern is formed by a photoetching process. During the process of forming the metal pattern, a metal layer needs to be formed on a base substrate first and then the metal layer is subjected to photoresist coating, exposure, developing, etching, and photoresist stripping, to obtain the metal pattern. Generally, the photoresist is stripped by means of dry etching.

### SUMMARY

Embodiments of the present disclosure provide a manufacturing method of an array substrate, an array substrate, a display panel and a display device. The technical solutions are as follows.

In an aspect, there is provided a manufacturing method of an array substrate, comprising: forming a metal layer on a base substrate; forming a protective layer on the side, away from the base substrate; of the metal layer, wherein the protective layer is configured to protect, the metal layer; forming photoresist on the side, away from the base substrate, of the protective layer; and processing the base substrate, on which the metal layer, the protective layer and the photoresist are formed, by means of a photoetching process to obtain a metal pattern.

Optionally, the protective layer is made from an insulating material or a non-metal conducting material.

Optionally, the protective layer is made from a transparent material.

Optionally, the protective layer is made from a metal inert material.

Optionally, the protective layer is made from any one of SiN_{X} or SiO₂ and indium tin oxide.

Optionally, a thickness range of the protective layer is [100 Å, 1000 Å].

Optionally, the metal layer is made of copper.

Optionally, forming the protective layer on the side, away from the base substrate, of the metal layer comprises: forming the protective layer on the side, away from the base substrate, of the metal layer by means of magnetron sputtering.

Optionally, the metal pattern is a source/drain metal pattern; prior to forming the metal layer on the base substrate, the method further comprises: sequentially forming a gate pattern, a gate insulating layer and an active layer on the base substrate; and forming the metal layer on the base substrate comprises: forming the metal layer at a side of the active layer away from the base substrate.

Optionally, processing the base substrate, on which the metal layer, the protective layer and the photoresist are formed, by means of a photoetching process to obtain the metal pattern comprises: sequentially performing exposure and developing on the photoresist to obtain a photoresist pattern; removing a portion, not covered with the photoresist pattern, of the protective layer by means of dry etching; removing a portion, not covered with the photoresist pattern, of the metal layer by means of wet etching; and removing the photoresist pattern by means of dry etching to obtain the metal pattern.

Optionally, the metal pattern is a source/drain metal pattern, before forming the metal layer on the base substrate, the manufacturing method further comprises: sequentially forming a gate pattern, a gate insulating layer and an active layer on the base substrate, performing exposure on the photoresist to obtain the photoresist pattern comprises: performing exposure on the photoresist by a mask plate with a semi-transparent region; performing developing on the photoresist subjected to exposure to obtain the photoresist pattern that comprises a semi-exposed portion, and before removing the photoresist pattern by means of dry etching to obtain the metal pattern, the manufacturing method further comprises: removing the portion, not covered with the photoresist pattern, of the active layer, the semi-exposed portion in the photoresist pattern and a remaining portion, covered with the semi-exposed portion, of the protective layer by means of dry etching; removing a remaining portion, not covered with the remaining photoresist pattern, of the rest metal layer by means of wet etching; and forming a groove in the portion, not covered with the remaining photoresist pattern, in the rest active layer by means of dry etching, to obtain an active layer pattern; wherein the gate pattern, the active layer pattern and the source/drain metal pattern form a thin film transistor, and the groove is a channel of the thin film transistor.

Optionally, after processing the base substrate, on which the metal layer, the protective layer and the photoresist are formed, by means of a photoetching process to obtain the metal pattern, a protective layer pattern is further formed on the side, away from the base substrate, of the metal pattern, and the manufacturing method further comprises: forming a passivation layer on the side, away from the base substrate, of the protective layer pattern, wherein the passivation layer and the protective layer are made from the same material.

In another aspect, there is provided an array substrate, comprising: a base substrate; a metal pattern on the base substrate; and a protective layer pattern on the side, away from the base substrate, of the metal pattern, wherein the protective layer pattern is configured to protect the metal pattern.

Optionally, an orthographic projection of the protective layer pattern on the base substrate coincides with an orthographic projection of the metal pattern on the base substrate.

Optionally, the protective layer pattern is made from an insulating material or a non-metal conducting material.

Optionally, the protective layer pattern is made from a transparent material.

Optionally, the protective layer pattern is made from a metal inert material.

Optionally, the protective layer pattern is made from any one of SiNₓ or SiO₂ and indium tin oxide.

Optionally, a thickness range of the protective layer pattern is [100 Å, 1000 Å].

Optionally, wherein the metal layer is made of copper.

Optionally, the metal pattern is a source/drain metal pattern; the array substrate further comprises: a gate pattern, a gate insulating layer and an active layer pattern sequentially between the metal pattern and the array substrate in a direction away from the base substrate, wherein the gate pattern, the active layer pattern and the source/drain metal pattern form a thin film transistor.

Optionally, the array substrate further comprises: a passivation layer on the side, away from the base substrate, of the protective layer pattern.

In yet another aspect, there is provided a display panel, comprising an array substrate, wherein the array substrate comprises: a base substrate; a metal pattern on the base substrate; and a protective layer pattern on the side, away from the base substrate, of the metal pattern, wherein the protective layer pattern is configured to protect the metal pattern.

Optionally, an orthographic projection of the proactive layer pattern on the base substrate coincides with an orthographic projection of the metal pattern on the base substrate.

Optionally, the protective layer is made from an insulating material or a non-metal conducting material.

Optionally, the protective layer is made from a transparent material.

Optionally, the protective layer is made from a metal inert material.

Optionally, the protective layer is made from any one of SiN_{X}, SiO2 and indium tin oxide.

Optionally, a thickness range of the protective layer pattern is [100 Å, 1000 Å].

Optionally, the metal layer is made of copper.

Optionally, the metal pattern is a source/drain metal pattern; and the array substrate further comprises: a gate pattern, a gate insulating layer and an active layer pattern sequentially between the metal pattern and the array substrate in a direction away from the base substrate, wherein the gate pattern, the active layer pattern and the source/drain metal pattern form a thin film transistor.

Optionally, the array substrate further comprises: a passivation layer on the side, away from the base substrate, of the protective layer pattern.

In still yet another aspect, there is provided a display device, comprising the display panel in the above aspect.

### BRIEF DESCRIPTION OF THE DRAWINGS

FIG. 1 is a flow chart of a manufacturing method of an array substrate according to an embodiment of the present disclosure;

FIG. 2 is a flow chart of another manufacturing method of an array substrate according to an embodiment of the present disclosure;

FIG. 3 is a schematic diagram of a an array substrate during a manufacturing process according to the embodiment of the present disclosure;

FIG. 4 is a schematic diagram of photoresist subjected to exposure and developing sequentially according to the embodiment of the present disclosure;

FIG. 5 is a schematic diagram of a protective layer after removal of the portion; not covered with a photoresist pattern according to the embodiment of the present disclosure;

FIG. 6 is a schematic diagram of a metal layer after removal of the portion not covered with the photoresist pattern according to the embodiment of the present disclosure;

FIG. 7 is a schematic diagram of an active layer after removal of the portion not covered with the photoresist pattern according to the embodiment of the present disclosure;

FIG. 8 is a schematic diagram obtained after removal of a semi-exposed portion in the photoresist pattern and the portion covered with the semi-exposed portion in the rest protective layer according to the embodiment of the present disclosure;

FIG. 9 is a schematic diagram obtained after removal of the portion not covered with the rest photoresist pattern in the rest metal layer according to the embodiment of the present disclosure;

FIG. 10 is a schematic diagram obtained after forming a groove in the portion, not covered with the remaining photoresist pattern, in the rest active layer according to the embodiment of the present disclosure;

FIG. 11 is a schematic diagram obtained after removal of a photoresist pattern according to the embodiment of the present disclosure; and

FIG. 12 is a structural schematic diagram of an array substrate according to an embodiment of the present disclosure.

### DETAILED DESCRIPTION

Generally, when a photoetching process is adopted to form a metal pattern, the photoresist is stripped by means of dry etching. However, when the photoresist is stripped by means of dry etching, the photoresist may react with the metal layer, which causes the metal layer to be oxidized, thereby causing the resistance of the metal layer finally formed to increase and affecting the electric conductivity of the metal pattern. It is known by the inventor that in addition to dry etching, photoresist may also be stripped by means of wet etching. However, during formation of a source/drain metal pattern of a TFT, if the photoresist is stripped by means of wet etching, the etching liquid may etch the metal layer that for forming the source/drain metal pattern. As a result, the metal of the metal layer diffuses to the channel of the TFT, which adversely affects the electric property of the channel of the TFT.

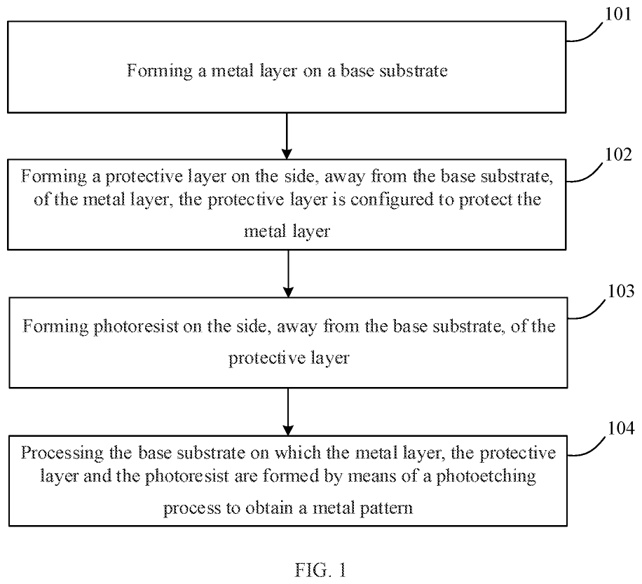

FIG. 1 is a flow chart of a manufacturing method of an array substrate according to an embodiment of the present disclosure. As shown in FIG. 1, the manufacturing method may include the following steps.

In step 101, a metal layer is formed on a base substrate.

For example, a layer of copper may be deposited on the base substrate by means of magnetron sputtering to serve as the metal layer.

In step 102, a protective layer is formed on the side, away from the base substrate, of the metal layer, and the protective layer is configured to protect the metal layer.

The thickness of the protective layer may be [100 Å, 1000 Å]. The protective layer may be made from an insulating material or a non-metal conducting material, and the protective layer may be made from a transparent material. The protective layer is made from a metal inert material, and thus the material of the protective layer does not react with the material of the metal layer. For example, the protective layer is made from SiNx, SiO₂, or Indium Tin Oxide (ITO). SiNx, SiO₂, and ITO are all transparent materials, and do not react with metal materials. SiNx and SiO₂ are insulating materials, and ITO is a non-metal conducting material.

In step 103, photoresist is formed on the side, away from the base substrate, of the protective layer.

The photoresist may be a photosensitive resin material. The photoresist may be a positive photoresist or negative photoresist.

In step 104, the base substrate on which the metal layer, the protective layer and the photoresist are formed is processed by means of a photoetching process to obtain a metal pattern.

The metal pattern may be a gate line, a data line, a gate pattern or a source/drain pattern. The photoetching process may include exposure, developing, etching and photoresist stripping. The photoresist stripping process may be a dry etching process.

In summary, according to the manufacturing method of the array substrate provided by the embodiment of the present disclosure, as the protective layer is formed between the metal layer and the photoresist during manufacture of the array substrate, the protective layer can protect the metal layer and prevent the photoresist from being in direct contact with the metal layer. Thus, when the photoresist is stripped by means of dry etching, the photoresist may be prevented from reacting with the metal layer, which guarantees the electric conductivity of the metal pattern finally formed.

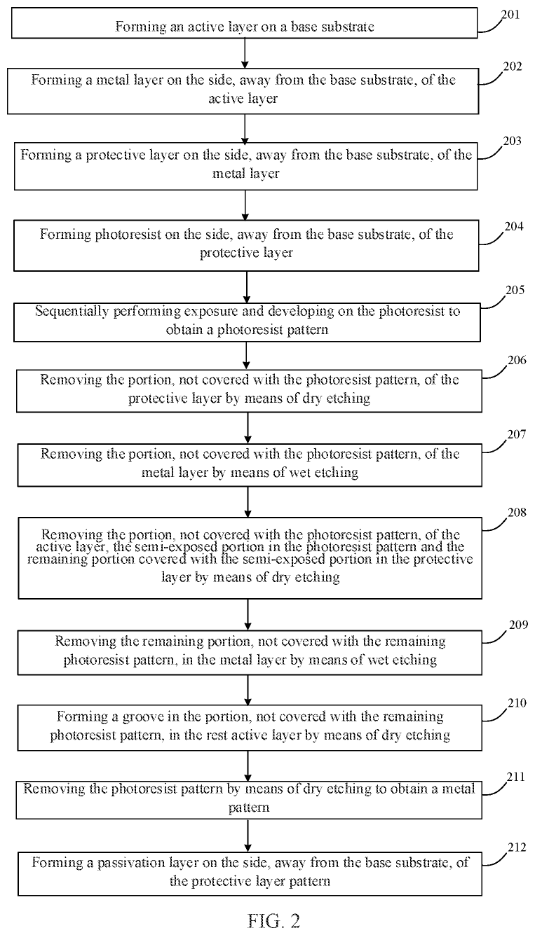

FIG. 2 is a flow chart of another manufacturing method of an array substrate according to an embodiment of the present disclosure. The embodiment of the present disclosure mainly takes formation of a source/drain metal pattern in the array substrate as an example for explanation. Referring to FIG. 2, the manufacturing method includes the following steps.

In step 201, an active layer is formed on a base substrate.

The base substrate may be a transparent glass substrate or a flexible substrate. The active layer may be made from amorphous silicon (a-Si), polysilicon or semiconductor oxide.

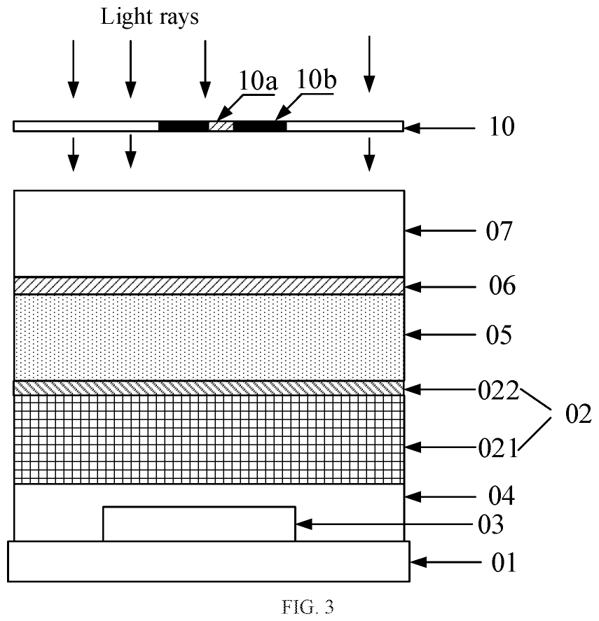

Exemplarily, FIG. 3 is a schematic diagram of an array substrate during the manufacturing process according to the embodiment of the present disclosure. As shown in FIG. 3, an a-Si layer 021 with a certain thickness may be deposited on the base substrate 01 by means of a Plasma. Enhanced Chemical Vapor Deposition (PECVD) process first. Then, an Ohmic contact layer 022 with relatively high electric conductivity is deposited on the side, away from the base substrate 01, of the a-Si layer 021 by means of a PECVD process. The Ohmic contact layer 022 may be a heavily-doped N-type semiconductor layer, for example, a phosphorus-doped a-Si layer. The a-Si layer 021 and the Ohmic contact layer 022 may constitute the active layer 02.

As shown in FIG. 3, before formation of the active layer 02, a gate pattern 03 and a gate insulating layer 04 have already been formed on the base substrate 01. The gate pattern 03 may be a gate metal pattern. Correspondingly, the active layer 02 may be formed on the side, away from the base substrate 01, of the gate insulating layer 04. Here, the processes for forming the gate pattern 03 and the gate insulating layer 04 may be made reference to the related art.

In step 202, a metal layer is formed on the side, away from the base substrate, of the active layer.

In the embodiment of the present disclosure, a metal layer may be deposited on the side, away from the base substrate, of the active layer by means of a magnetron sputtering process. The metal layer may be made of copper. Certainly, the metal layer may also be made of other metal materials, such as molybdenum, aluminum, etc.

Exemplarily, as shown in FIG. 3, the metal layer 05 may be formed on the side, away from the base substrate 01, of the active layer 02. Persons of ordinary skill in the art easily understand that an interlayer dielectric layer (not shown in FIG. 3) may be formed on the side, away from the base substrate 01, of the active layer, before forming the metal layer 05 on the side, away from the base substrate 01, of the active layer 02. Correspondingly, the metal layer 05 may be formed on the side, away from the base substrate 01, of the interlayer dielectric layer. The interlayer dielectric layer may be an insulating layer.

In step 203, a protective layer is formed on the side, away from the base substrate, of the metal layer.

In the embodiment of the present disclosure, a protective layer may be formed on the side, away from the base substrate, of the metal layer by means of magnetron sputtering. The protective layer is mainly used to protect the metal layer and to prevent the metal layer from being in direct contact with the photoresist formed subsequently. Here, the protective layer may totally cover the metal layer. The thickness range of the protective layer may be [100 Å, 1000 Å]. For example, the thickness of the protective layer is 500 Å. The protective layer may be made from an insulating material or a non-metal conducting material. In addition, the protective layer may be made from a metal inert material. The electron accepting ability of material of the protective layer may be lower than the electron giving ability of the material of the metal layer. Therefore, the material of the protective layer does not react with the material of the metal layer. In this way, the protective layer is prevented from adversely affecting the electric property of the metal pattern finally formed. Optionally, the material of the protective layer may be a transparent material. Thus, the protective layer is prevented from adversely affecting the light transmittance of the array substrate, thereby preventing the protective layer from adversely affecting the light transmittance of the display panel that includes the array substrate. Besides, the material of the protective layer may be etched by the dry etching process to guarantee that the protective layer may be stripped. In the embodiment of the present disclosure, the protective layer may be made from any one of SiN_{X}, SiO₂ and ITO.

Exemplarily, as shown in FIG. 3, the protective layer 06 may be formed on the side, away from the base substrate 01, of the metal layer 05. The protective layer 06 may totally cover the metal layer 05.

In step 204, photoresist is formed on the side, away from the base substrate, of the protective layer.

Exemplarily, as shown in FIG. 3, the side, away from the base substrate 01, of the protective layer 06 may be coated with a layer of photoresist 07. The photoresist 07 may cover the whole protective layer 06. The photoresist 07 may be made from a photosensitive resin material, and it may be a positive photoresist or a negative photoresist.

In step 205, exposure and developing are sequentially performed on the photoresist to obtain a photoresist pattern.

In the embodiment of the present disclosure, in accordance with the shape of the metal pattern to be formed, exposure may be performed on the photoresist by a mask plate with a light-transmitting region or light-proof region of which the shape is identical to that of the metal pattern. Developing is performed on the photoresist subjected to exposure with developing liquid to obtain the photoresist pattern.

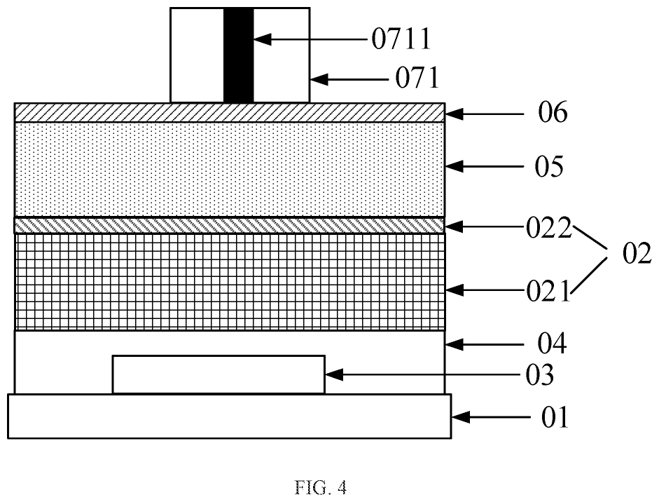

Optionally, if the metal pattern to be formed is a source/drain metal pattern in a TFT, as shown in FIG. 3, the mask plate 10 may further include a semi-light-transmitting region 10a. The orthographic projection of the semi-light-transmitting region 10a on the base substrate 01 coincides with the region in which the channel of the TFT is to be formed. FIG. 4 is a schematic diagram obtained after exposure and developing are sequentially performed on the photoresist 07 according to the embodiment of the present disclosure, A photoresist pattern 071 may be obtained after the developing liquid is adopted to perform developing on the photoresist 07 subjected to exposure. The photoresist pattern 071 may include a semi-exposed portion 0711.

If the photoresist 07 is a positive photoresist, as shown in FIG. 3, exposure may be performed on the photoresist 07 by a mask plate with a light-proof region 10b of which the shape is identical to that of the source/drain metal pattern to be formed, and developing is performed on the photoresist 07 subjected to exposure to obtain the photoresist pattern 071 shown in FIG. 4. If the photoresist 07 is a negative photoresist, exposure may be performed on the photoresist by a mask plate with a light-transmitting region of which the shape is identical to that of the source/drain metal pattern to be formed, and developing is performed on the photoresist subjected to exposure to obtain the photoresist pattern 071 shown in FIG. 4.

In step 206, the portion, not covered with the photoresist pattern, of the protective layer is removed by means of dry etching.

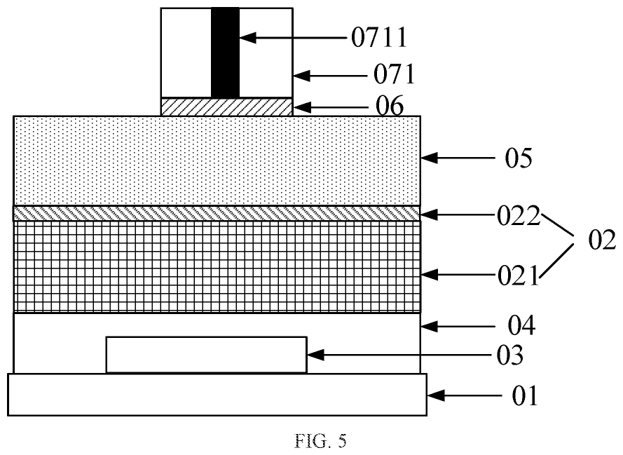

Exemplarily, the portion, not covered with the photoresist pattern 071, of the protective layer 06 shown in FIG. 4 may be removed by means of dry etching. Optionally, FIG. 5 is a schematic diagram obtained after the portion, not covered with the photoresist pattern 071, of the protective layer 06 is removed.

In step 207, the portion, not covered with the photoresist pattern, of the metal layer is removed by means of wet etching.

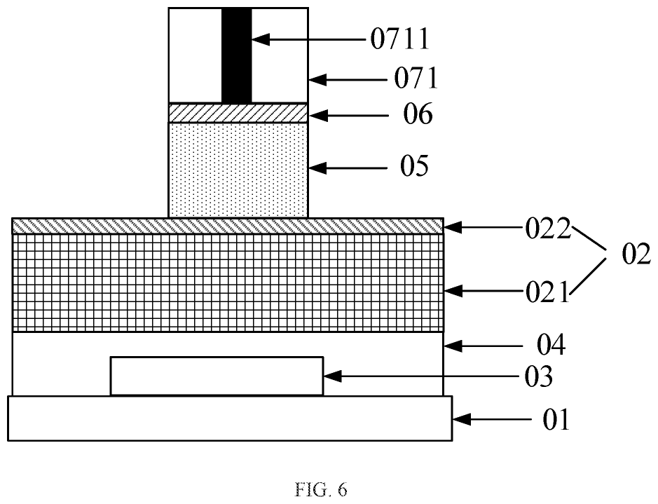

Exemplarily, the portion, not covered with the photoresist pattern 071, of the metal layer 05 shown in FIG. 5 may be removed by means of wet etching. Optionally, FIG. 6 is a schematic diagram obtained after the portion, not covered with the photoresist pattern 071, of the metal layer 05 is removed.

In the embodiment of the present disclosure, generally, a film formed by a non-metal material is removed by means of dry etching, and a film formed by a metal material is removed by wet etching.

In step 208, the portion, not covered with the photoresist pattern, of the active layer, the semi-exposed portion in the photoresist pattern and the remaining portion, covered with the semi-exposed portion, in the protective layer are removed by means of dry etching.

The semi-exposed portion is in a region for forming the channel of the TFT. In other words, the orthographic projection region of the semi-exposed portion on the active layer coincides with the region for forming the channel of the TFT on the active layer.

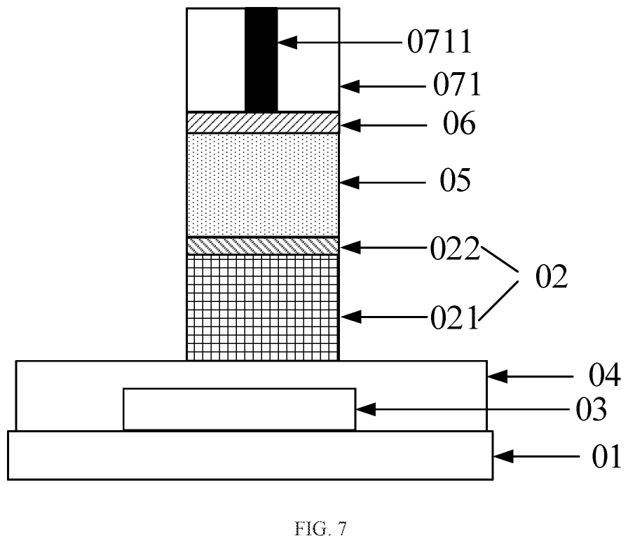

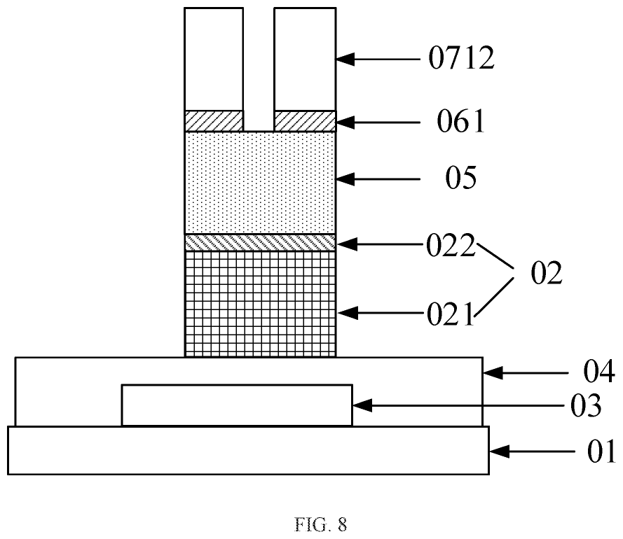

Exemplarily, as shown in FIG. 6, the portion, not covered with the photoresist pattern 071, of the active layer 02, the semi-exposed portion 0711 in the photoresist pattern 071, and the remaining portion, covered with the semi-exposed portion 0711, in the protective layer 06 may be removed by means of dry etching. Optionally, FIG. 7 is a schematic diagram obtained after the portion, not covered with the photoresist pattern 071, in the active layer 02 is removed. FIG. 8 is a schematic diagram obtained after the portion, not covered with the photoresist pattern 071, in the active layer 02, the semi-exposed portion 0711 in the photoresist pattern 071 and the remaining portion, covered with the semi-exposed portion 0711, in the protective layer 06 are removed.

The embodiment of the present disclosure takes that the semi-exposed portion 0711 in the photoresist pattern 071 and the remaining portion, covered with the semi-exposed portion 0711, in the protective layer 06 are removed by means of a dry etching as an example for explanation. As shown in FIG. 7, the semi-exposed portion 0711 in the photoresist pattern 071 and the remaining portion, covered with the semi-exposed portion 0711, in the protective layer 06 may be further asked to remove the semi-exposed portion 0711 in the photoresist pattern 071 and the remaining portion, covered with the semi-exposed portion 0711, in the protective layer 06.

In step 209, the remaining portion, not covered with the remaining photoresist pattern, in the metal layer is removed by means of wet etching.

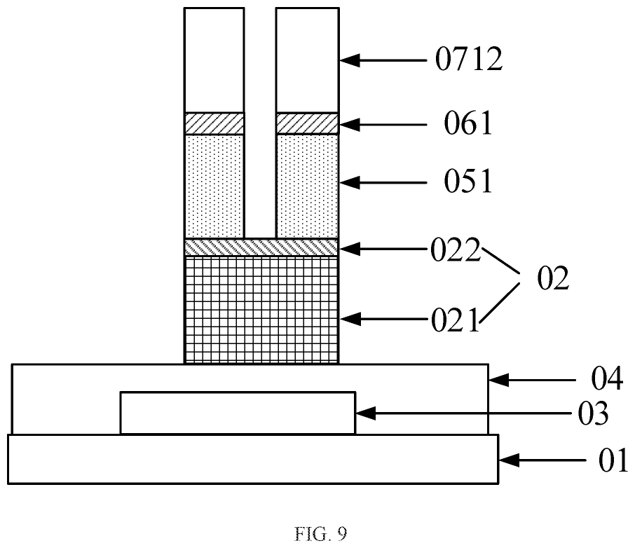

Exemplarily, as shown in FIG. 8, the remaining portion, not covered with the remaining photoresist pattern 0712, in the metal layer 05 may be removed by means of wet etching. Optionally, FIG. 9 is a schematic diagram obtained after the remaining portion, not covered with the remaining photoresist pattern 0712, in the metal layer 05 is removed.

In step 210, a groove is formed in the portion, not covered with the remaining photoresist pattern, in the rest active layer by means of dry etching.

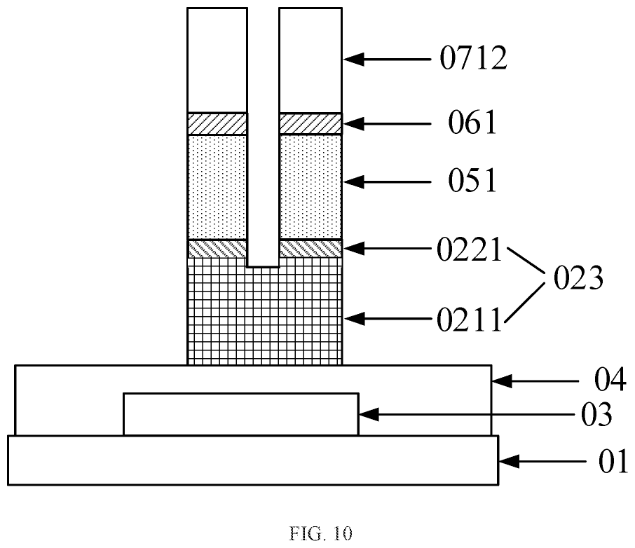

Exemplarily, as shown in FIG. 9, the groove may be formed in the portion, not covered with the remaining photoresist pattern 0712, in the rest active layer 02 by means by dry etching to obtain an active layer pattern. Optionally, FIG. 10 is a schematic diagram obtained after the groove (not shown) is formed in the portion, not covered with the remaining photoresist pattern 0712, in the rest active layer 02, The active layer pattern 023 is obtained after a groove is formed in the portion, not covered with the remaining photoresist pattern 0712, in the rest active layer 02.

In step 211, the photoresist pattern is removed by means of dry etching to obtain a metal pattern.

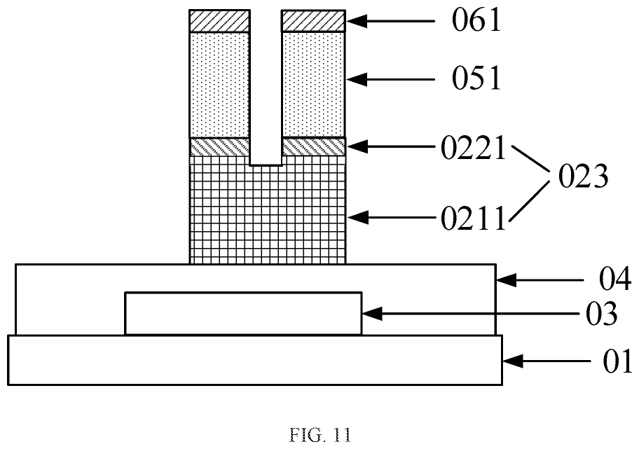

Exemplarily, as shown in FIG. 10, the remaining photoresist pattern 0712 may be removed by means of dry etching to obtain the metal pattern 051. Optionally, FIG. 11 is a schematic diagram obtained after the remaining photoresist pattern 0712 is removed. As shown in FIG. 11, after removal of the remaining photoresist pattern 0712 shown in FIG. 10, a protective layer pattern 061 is further formed on the side, away from the base substrate 01, of the metal pattern 051. The metal pattern 051 shown in FIG. 11 may be a source/drain metal pattern.

Here, the gate pattern 03, the active layer pattern 023 and the source/drain metal pattern form a TFT. The groove in the active layer pattern 023 is a channel of the TFT.

In the embodiments, when the protective layer is made from a conducting material, since the protective layer pattern is in direct contact with the metal pattern, signals in the metal pattern can be directly transmitted to the protective layer pattern. Thus, the protective layer pattern can be a part of the metal pattern. The film thickness of the metal pattern is smaller than the film thickness of the metal pattern needed to be formed when no protective layer pattern is arranged, which can avoid the arrangement of the protective layer pattern from affecting the property of the metal pattern. In step 202, the film thickness of the metal layer may be controlled by controlling the deposition duration of the material of the metal layer, to control the film thickness of the metal pattern. When the deposition duration of the material of the metal layer is long, the metal layer finally formed is relatively thick. The deposition duration is positively correlated with the film thickness.

The metal pattern 051 and the protective layer pattern 061 are described in step 211 of the embodiment of the present disclosure. It can be known from steps 208 and 209 that the protective layer pattern 061 is actually formed in step 208, and the metal pattern 051 is actually formed in step 209.

In the embodiment of the present disclosure, as a protective layer pattern is disposed between the metal pattern and the photoresist, the metal pattern and the photoresist are not in direct contact. When the photoresist pattern is removed by means of dry etching, the photoresist will not react with the metal pattern, which can preventing the metal pattern from being oxidized, and prevent the resistance of the metal pattern from increasing, thereby effectively guaranteeing the electric conductivity of the metal pattern formed. In the embodiment of the present disclosure, the photoresist pattern may also be removed by means of wet etching. Since the protective layer is disposed between the metal pattern and the photoresist pattern, the etching liquid may be prevented from etching the metal pattern, thereby preventing the metal from diffusing into the channel of the TFT to adversely affect its electric property. Thus, the performance of the metal pattern finally formed is effectively guaranteed.

In step 212, a passivation layer is formed on the side, away from the base substrate, of the protective layer pattern.

Optionally, the passivation (PVX) layer may be formed on the side, away from base substrate, of the protective layer pattern by means of PECVD. The passivation layer may also serve as an electrolytic medium. The passivation layer may be made from an insulating material. When the protective layer is made from an insulating material, the passivation layer may be made from the same material as the protective layer, e.g., SiN_{X} or SiO₂.

Exemplarily, as shown in FIG. 11, the passivation layer 08 may be formed on the side, away from the base substrate 01, of the protective layer pattern 061 to obtain the array substrate. Optionally, FIG. 12 is a structural schematic diagram of an array substrate.

When the protective layer is made from an insulating material, the protective layer pattern and the passivation layer may be made from the same material. Thus, the protective layer pattern may serve as part of the passivation layer. The film thickness of the passivation layer may be smaller than that of the passivation layer to be formed when the protective layer pattern is not disposed, such that the property of the passivation layer will not be affected by the protective layer pattern. The film thickness of the passivation layer may be controlled by controlling the deposition duration of material of the passivation layer. During formation of the passivation layer by the vapor deposition method, when the deposition duration of material of the passivation is relatively long, the passivation layer finally formed will be relatively thick, That is, the deposition duration of material of the passivation layer is in direct proportion to the film thickness thereof.

In summary, according to the manufacturing method of the array substrate provided by the embodiment of the present disclosure, a protective layer is formed between the metal layer and the photoresist during manufacture of the array substrate, and the protective layer can protect the metal layer and prevent the photoresist from being in direct contact with the metal layer. Thus, when the photoresist is stripped by means of dry etching, the photoresist may be prevented from reacting with the metal layer, which guarantees the electric conductivity of the metal pattern finally formed.

FIG. 12 illustrates an array substrate provided by an embodiment of the present disclosure. The array substrate may be manufactured by the manufacturing method shown in FIG. 1 or FIG. 2. As shown in FIG. 12, the array substrate may include a base substrate 01, a metal pattern 051 on the base substrate 01 and a protective layer pattern 061 on the side, away from the base substrate 01, of the metal pattern 051. The protective layer pattern 061 is configured to protect the metal pattern 051.

In summary, according to the array substrate provided by the embodiment of the present disclosure, as the protective layer is formed between the metal layer and the photoresist during manufacture of the array substrate, the protective layer can protect the metal layer and prevent the photoresist from being in direct contact with the metal layer. Thus, when the photoresist is stripped by means of dry etching, the photoresist may be prevented from reacting with the metal layer, which guarantees the electric conductivity of the metal pattern finally formed, thereby guaranteeing the property of the array substrate.

Optionally, the orthographic projection of the protective layer pattern 061 on the base substrate 01 coincides with the orthographic projection of the metal pattern 051 on the base substrate 01.

Optionally, as shown in FIG. 12, the metal pattern 051 may be a source/drain metal pattern. Correspondingly, the array substrate may further include a gate pattern 03, a gate insulating layer 04 and an active layer pattern 023 sequentially between the base substrate 01 and the metal pattern 051 in the direction away from the base substrate 01, The gate pattern 03, the active layer pattern 023 and the source/drain metal pattern form a TFT.

Optionally, as shown in FIG. 12, the array substrate may further include a passivation layer 08 on the side, away from the base substrate 01, of the protective layer pattern 061.

Optionally, the protective layer pattern 061 is made from an insulating material or a non-metal conducting material. When the protective layer pattern 061 is made from an insulating material, the passivation layer 08 and the protective layer pattern 061 may be made from the same material. The protective layer pattern 061 may be part of the passivation layer 08, When the protective layer pattern 061 is made from a non-metal conducting material, the protective layer pattern 061 may be part of the metal pattern 051.

Optionally, the protective layer pattern 061 is made from a transparent material.

Optionally, the protective layer pattern 061 is made from a metal inert material. The electron accepting ability of the material of the protective layer pattern 061 is lower than the electron giving ability of the material of the metal pattern 051. Therefore, the material of the protective layer pattern 061 does not react with the material of which the metal pattern 051.

Optionally, the protective layer pattern 061 is made from any one of silicon nitride, silicon dioxide and indium tin oxide, and the metal pattern 051 may be made of copper.

Optionally, the thickness range of the protective layer pattern 061 is [100 Å, 1000 Å]. For example, the thickness of the protective layer pattern 061 is 500 Å.

In summary, according to the array substrate provided by the embodiment of the present disclosure, as the protective layer is formed between the metal layer and the photoresist during manufacture of the array substrate, the protective layer can protect the metal layer and prevent the photoresist from being in direct contact with the metal layer. Thus, when the photoresist is stripped by means of dry etching, the photoresist may be prevented from reacting with the metal layer, which guarantees the electric conductivity of the metal pattern finally formed, thereby guaranteeing the property of the array substrate.

An embodiment of the present disclosure provides a display panel which may include the array substrate as shown in FIG. 12, The display panel may be a liquid crystal display panel or an Organic Light-Emitting Diode (OLED) display panel.

An embodiment of the present disclosure provides a display device which may include the array substrate as shown in FIG. 12. The display device may be any product or part with a display function, such as, a liquid crystal panel, an OLED panel, electronic paper, a mobile phone, a tablet PC, a wearable device, a television, a display, a laptop, a digital photo frame or a navigator.

The foregoing descriptions are only exemplary embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A manufacturing method of an array substrate, comprising:
forming a metal layer on a base substrate;
forming a protective layer on the side, away from the base substrate, of the metal layer, wherein the protective layer is configured to protect the metal layer;
forming photoresist on the side, away from the base substrate, of the protective layer; and
processing the base substrate, on which the metal layer, the protective layer and the photoresist are formed, by means of a photoetching process to obtain a metal pattern.

2-3. (canceled)

4. The manufacturing method according to claim 1, wherein the protective layer is made from an insulating material or a non-metal conducting material.

5. The manufacturing method according to claim 1, wherein the protective layer is made from a metal inert material.

6. (canceled)

7. The manufacturing method according to claim 1, wherein the protective layer is made from any one of SiNX, SiO2 and indium tin oxide.

8. The manufacturing method according to claim 1, wherein forming the protective layer on the side, away from the base substrate, of the metal layer comprises:
forming the protective layer on the side, away from the base substrate, of the metal layer by means of magnetron sputtering.

9. The manufacturing method according to claim 1, wherein processing the base substrate, on which the metal layer, the protective layer and the photoresist are formed, by means of a photoetching process to obtain the metal pattern comprises:
sequentially performing exposure and developing on the photoresist to obtain a photoresist pattern;
removing a portion, not covered with the photoresist pattern, of the protective layer by means of dry etching;
removing a portion, not covered with the photoresist pattern, of the metal layer by means of wet etching; and
removing the photoresist pattern by means of dry etching to obtain the metal pattern.

10. The manufacturing method according to claim 9, wherein the metal pattern is a source/drain metal pattern, before forming the metal layer on the base substrate, the manufacturing method further comprises:
sequentially forming a gate pattern, a gate insulating layer and an active layer on the base substrate,
sequentially performing exposure and developing on the photoresist to obtain the photoresist pattern comprises:
performing exposure on the photoresist by a mask plate with a semi-transparent region;
performing developing on the photoresist subjected to exposure to obtain the photoresist pattern that comprises a semi-exposed portion, and
before removing the photoresist pattern by means of dry etching to obtain the metal pattern, the manufacturing method further comprises:
removing the portion, not covered with the photoresist pattern, of the active layer, the semi-exposed portion in the photoresist pattern and a remaining portion, covered with the semi-exposed portion, of the protective layer by means of dry etching;
removing a remaining portion, not covered with the remaining photoresist pattern, of the rest metal layer by means of wet etching; and
forming a groove in the portion, not covered with the remaining photoresist pattern, in the rest active layer by means of dry etching, to obtain an active layer pattern;
wherein the gate pattern, the active layer pattern and the source/drain metal pattern form a thin film transistor, and the groove is a channel of the thin film transistor.

11. The manufacturing method according to claim 1, wherein after processing the base substrate, on which the metal layer, the protective layer and the photoresist are formed, by means of a photoetching process to obtain the metal pattern, a protective layer pattern is further formed on the side, away from the base substrate, of the metal pattern, and the manufacturing method further comprises:
forming a passivation layer on the side, away from the base substrate, of the protective layer pattern, wherein the passivation layer and the protective layer are made from the same material.

12. An array substrate, comprising:
a base substrate;
a metal pattern on the base substrate; and
a protective layer pattern on the side, away from the base substrate, of the metal pattern, wherein an orthographic projection of the proactive layer pattern on the base substrate coincides with an orthographic projection of the metal pattern on the base substrate, and the protective layer pattern is configured to protect the metal pattern.

13-15. (canceled)

16. The array substrate according to claim 12, wherein the protective layer pattern is made from an insulating material or a non-metal conducting material, and the protective layer pattern is made from a metal inert material.

17. (canceled)

18. The array substrate according to claim 12, wherein the protective layer pattern is made from any one of SiNx or SiO2 and indium tin oxide.

19. (canceled)

20. A display device, comprising an array substrate, wherein the array substrate comprises:
a base substrate; a metal pattern on the base substrate; and a protective layer pattern on the side, away from the base substrate, of the metal pattern, wherein an orthographic projection of the proactive layer pattern on the base substrate coincides with an orthographic projection of the metal pattern on the base substrate, and the protective layer pattern is configured to protect the metal pattern.

21. The manufacturing method according to claim 1, wherein the protective layer is made from a transparent material.

22. The manufacturing method according to claim 1, wherein a thickness range of the protective layer is [100 Å, 1000 Å].

23. The manufacturing method according to claim 1, wherein the metal layer is made of copper.

24. The manufacturing method according to claim 1, wherein the metal pattern is a source/drain metal pattern; prior to forming the metal layer on the base substrate, the method further comprising:
sequentially forming a gate pattern, a gate insulating layer and an active layer on the base substrate; and
forming the metal layer on the base substrate comprises: forming the metal layer on a side of the active layer away from the base substrate.

25. The array substrate according to claim 12, wherein the protective layer pattern is made from a transparent material.

26. The array substrate according to claim 12, wherein a thickness range of the protective layer pattern is [100 Å, 1000 Å].

27. The array substrate according to claim 12, wherein the metal layer is made of copper.

28. The array substrate according to claim 12, wherein the metal pattern is a source/drain metal pattern; the array substrate further comprises: a gate pattern, a gate insulating layer and an active layer pattern sequentially between the metal pattern and the array substrate in a direction away from the base substrate, and a passivation layer on the side, away from the base substrate, of the protective layer pattern, wherein the gate pattern, the active layer pattern and the source/drain metal pattern form a thin film transistor.
